(19) United States
(12) Patent Application Publication
(10) Pub. No.: US 2010/0327260 A1
(43) Pub. Date: Dec. 30, 2010

(54) Single Electron Transistor Operating at Room Temperature and Manufacturing Method for Same

(75) Inventors: Jung Bum Choi, Cheongju-si (KR); Seung Jun Shin, Pyeongchang-gun (KR)

Correspondence Address: FENWICK & WEST LLP, SILICON VALLEY CENTER, 801 CALIFORNIA STREET, MOUNTAIN VIEW, CA, 94041, US

(73) Assignee: Chungbuk National University Industry-Academic Cooperation Foundation, Cheongju-si, Chungcheongbuk-do (KR)

(21) Appl. No.: 12/866,886

(22) PCT Filed: Feb. 13, 2009
(86) PCT No.: PCT/KR2009/000707

§ 371 Date: Aug. 9, 2010

(30) Foreign Application Priority Data
Feb. 16, 2008 (KR) 10-2008-0014230
Aug. 5, 2008 (KR) 10-2008-0076550
Feb. 9, 2009 (KR) 10-2009-0010087

(51) Int. Cl. H01L 29/12; H01L 21/762

(52) U.S. Cl. 257/24; 438/689; 438/149; 977/762; 977/937; 257/E21.561; 257/E29.071; 257/E21.002

(57) ABSTRACT

The present invention relates to a single electron transistor operating at room temperature and a manufacturing method for same. More particularly, the present invention relates to a single electron transistor operating at room temperature, in which a quantum dot or a silicide quantum dot using a nanostructure is formed and a gate is positioned on the quantum dot so as to minimize influence on a tunneling barrier and achieve improved effectiveness in electric potential control for the quantum dot and operating efficiency of the transistor, and a manufacturing method for same.

### FIELD OF THE INVENTION

The present invention relates to a single-electron transistor (SET) operating at room temperature and a method of manufacturing the same, and to be specific, to a single-electron transistor operating at room temperature and a method of manufacturing the same, which are capable of minimizing influence of the gate voltage on tunneling barriers by a gate and effectively controlling the electric potential of a quantum dot (QD) and improving the efficiency of an operation, by forming the silicide quantum dot using a nano structure and placing the gate on the quantum dot.

### BACKGROUND OF THE RELATED ART

In semiconductor technology, high-integration, high-speed, and low-power semiconductor devices are being developed in order to store a greater amount of information. The scale-down process of the semiconductor devices resulting from the development of technology inevitably encounters a physical limit. A single-electron transistor using a single-electron tunneling phenomenon, emerged at such a critical point, is expected to replace the complementary metal oxide semiconductor (CMOS) devices. Research has actively been carrying out on the single-electron transistor in order to apply it to the next-generation Tera-level integrated circuit devices.

The single-electron transistor must include a tunneling barrier between the quantum dot and the source (and also the drain) because it uses a tunneling phenomenon. The tunneling barrier is naturally formed by a pattern-dependant oxidation (PADOX) process when a gate oxide film is formed.

Recently, with the rapid development of the integrated circuits, computers, portable terminals, etc., having a high degree of an information processing function, are being spread. Such equipments with the high functionality require semiconductor devices with low power consumption, together with a high degree of integration density, because they require high power consumption.

One of the technologies developed in order to comply with these needs is the single-electron transistor. The single-electron transistor is advantageous in that it can greatly reduce power consumption to the microwatt level, whereby it is easy to be highly integrated because it can control the ON/OFF switching current using one electron.

The single-electron transistor, however, has the following problems.

1) The single-electron transistor requires a fine electrode structure in order to efficiently control single-electron because the control is accomplished by one electron.

2) The single-electron transistor controls single-electron through a tunneling barrier formed between the source and the drain using a tunneling phenomenon, but the tunneling barrier is naturally formed when a gate oxide film is formed, making it difficult to intentionally control the height and width of the tunneling barrier.

3) The gate is used to control the electric potential of a quantum dot using the formed tunneling barrier. Here, a conventional single-electron transistor is operated only at low temperature because the tunneling barriers are influenced by the gate.

4) In particular, the gate is formed to cover the source and the drain regions as well as the quantum dot. Thus, the electric potential applied to the gate not only changes the electric potential of the quantum dot, but also influences the tunneling barriers formed on the left and right sides of the quantum dot.

5) When the gate voltage increases as described above, the height of the tunneling barriers is lowered. Consequently, the characteristic of Coulomb oscillation is deteriorated.

### DETAILED DESCRIPTION OF THE INVENTION

### Technical Subjects of the Invention

Accordingly, the present invention has been made in view of the above problems occurring in the conventional technology, and it is an object of the present invention to provide a single-electron transistor operating at room temperature and a method of manufacturing the same. To be specific, the object of the present invention is to provide a single-electron transistor (SET) operating at room temperature and a method of manufacturing the same, which are capable of minimizing influence of the gate voltage on tunneling barriers by a gate and effectively controlling the electric potential of a quantum dot (QD), by forming the silicide quantum dot using a nano structure and placing the gate on the quantum dot.

### Technical Resolutions of the Invention

A method of manufacturing the single-electron transistor includes a first step of forming a nano-wire structure over the upper conductive layer of a substrate in which a lower conductive layer, a first insulation film, and an upper conductive layer are stacked; a second step of implanting the upper conductive layer with impurities using the nano structure as a mask; a third step of forming a second insulation film over the upper conductive layer so that the nano-wire structure is covered; a fourth step of etching the upper conductive layer and the second insulation layer, thereby forming a quantum dot; a fifth step of forming a third insulation film by a thermal oxidation process to surround the quantum dot; a sixth step of forming a gate over the quantum dot.

The quantum dot is formed by fully etching the nano-wire structure and the second insulation film and then etching a part of a thickness of the upper conductive layer, or the quantum dot is formed by partially etching the nano-wire structure together with the upper conductive layer and the second insulation film.

Another method of manufacturing the single-electron transistor includes a first step of defining a nano-wire structure over a substrate; a second step of forming a second insulation film over the substrate so that the nano structure is covered; a third step of forming a trench by etching so that the nano structure is exposed, thereby forming a quantum dot; a fourth step of forming a third insulation film with a constant thickness on surfaces of the second insulation film and the trench; and a fifth step of forming a gate in the trench 31 so that the gate is positioned over the quantum dot.

The first, second, and third insulation films are an oxidation film or an insulation film, and the conductive layer is silicon.

Between the fourth step and the fifth step, a sixth step of etching the plane layer of the third insulation film, formed by a deposition process; and a seventh step of implanting regions other than the quantum dot with impurities using the gate as a mask after etching the second insulation film and the third insulation film, can be further included.

A lower conductive layer used as a lower gate is further included under the first insulation layer.

The seventh step further comprises forming sidewall spacers in the gate, and is characterized by using the gate and the sidewalls as a mask.

Another method of manufacturing the single-electron transistor includes a first step of forming a nano structure by etching a conductive layer of a SOI substrate in which a first insulation film and the conductive layer are sequentially stacked; a second step of depositing a second insulation film over the substrate so that the nano structure is covered; a third step of forming a trench by etching a portion of the second insulation film so that a part of the nano structure is exposed; a fourth step of etching the exposed nano structure, thereby forming a quantum dot; a fifth step of forming a metal film by depositing metal material over the second insulation film, the trench and the quantum; a sixth step of forming a silicide quantum dot by performing an thermal annealing process for the metal film and the quantum dot; a seventh step of removing the metal film which has not reacted to the quantum dot; a eight step of depositing a third insulation film on the silicide quantum dot and surfaces from which the metal film has been removed; and an ninth step of filling a the trench on which the third insulation film is deposited with a gate.

The eight step includes depositing a third insulation film after fully or partially removing a second insulation film; the ninth step further comprises forming sidewall spacers in a gate and implanting impurities using the gate and the sidewall spacers as a mask, thereby forming a source and a drain.

The first, second, and third insulation films are an oxidation film or an insulation film, and the conductive layer is silicon; a lower conductive layer used as a lower gate is provided under the first insulation layer.

Meanwhile, the present invention relates to a single-electron transistor which is manufactured by the above-described methods and operated at room temperature.

### ADVANTAGEOUS EFFECTS

As described above, the present invention has the following advantages.

1) Since the gate is formed just over the quantum dot, the influence on the tunneling barriers can be minimized.

2) A reduction in the height of the tunneling barrier resulting from electric potential of the gate can be reduced. Accordingly, the operating temperature of the single-electron transistor can rise.

3) Since the conventional CMOS processes can be used without change, the process costs can be reduced and the manufacturing processes can be simplified.

4) Since one or multiple silicide quantum dots are formed in series, the total capacitance of the single-electron transistor can be reduced, and the operating efficiency can be improved.

5) silicide quantum dots having an uniform size and a constant density distribution can be formed, thereby forming more stable quantum dots.

### BRIEF DESCRIPTION OF THE DRAWINGS

Further objects and advantages of the invention can be more fully understood from the following detailed description taken in conjunction with the accompanying drawings in which:

FIG. 1 is a sectional perspective view showing a state in which a nano-wire structure is formed according to the first embodiment of the present invention;

FIG. 2 is a sectional perspective view showing a state in which a second insulation film is formed according to the first embodiment of the present invention;

FIG. 3 is a sectional perspective view showing an example in which a quantum dot is formed according to the first embodiment of the present invention;

FIG. 4 is a sectional perspective view showing a state in which a third insulation film is formed according to the first embodiment of the present invention;

FIG. 5 is a sectional perspective view showing a state in which a gate is formed according to the first embodiment of the present invention;

FIG. 6 is a partially sectional perspective view showing an example of a substrate to be used for a manufacturing method of the single-electron transistor according to the second embodiment of the present invention;

FIG. 7 is a partially sectional perspective view showing a state in which a nano-wire structure is formed according to the second embodiment of the present invention;

FIG. 8 is a partially sectional perspective view showing a state in which a second insulation film is formed according to the second embodiment of the present invention;

FIG. 9 is a partially sectional perspective view showing an example in which a quantum dot is formed according to the second embodiment of the present invention;

FIG. 10 is a partially sectional perspective view showing another example in which a quantum dot is formed according to the second embodiment of the present invention;

FIG. 11 is a partially sectional perspective view showing a state in which a third insulation film is formed according to the second embodiment of the present invention;

FIG. 12 is a partially sectional perspective view showing a state in which a gate is formed according to the second embodiment of the present invention;

FIG. 13 is a partially sectional perspective view showing a state in which a third insulation film is etched according to the second embodiment of the present invention;

FIG. 14 is a partially sectional perspective view showing that a sidewall spacer is formed in the etched state of the third insulation film, as shown in FIG. 13;

FIG. 15 is a flow chart showing a method of manufacturing a single-electron transistor operating at room temperature according to the third embodiment of the present invention;

FIG. 16 is a perspective view showing an example of a substrate to be used for manufacturing method according to the third embodiment of the present invention;

FIG. 17 is a partially sectional perspective view showing a state in which a nano structure is defined according to the third embodiment of the present invention;

FIG. 18 is a partially sectional perspective view showing a state in which a second insulation film is formed according to the third embodiment of the present invention;

FIG. 19 is a partially sectional perspective view showing a state in which a trench is formed according to the third embodiment of the present invention;

FIG. 20 is a partially sectional perspective view showing a state in which a quantum dot is formed according to the third embodiment of the present invention;

FIG. 21 is a partially sectional perspective view showing a state in which a metal film is deposited according to the third embodiment of the present invention;

FIG. 22 is a partially sectional perspective view showing a state in which a silicide quantum dot is formed according to the third embodiment of the present invention;

FIG. 23 is a cross-sectional view showing a first example of a silicide quantum dot according to the third embodiment of the present invention;

FIG. 24 is a cross-sectional view showing a second example of a silicide quantum dot according to the third embodiment of the present invention;

FIG. 25 is a partially sectional perspective view showing a state a metal film is removed according to the third embodiment of the present invention;

FIG. 26 is a partially sectional perspective view showing a state in which a third insulation film is formed according to the third embodiment of the present invention;

FIG. 27 is a partially sectional perspective view showing a state in which a gate is filled up according to the third embodiment of the present invention;

FIG. 28 is a cross-sectional perspective view showing a state in which second and third insulation films are etched according to the third embodiment of the present invention;

FIG. 29 is a cross-sectional perspective view showing that a sidewall spacer is formed in the etched state, as shown in FIG. 28.

### DESCRIPTION OF REFERENCE NUMERALS OF PRINCIPAL ELEMENTS IN THE DRAWINGS

| | |
|---|---|
| 10: first insulation film | 20: conductive layer |
| 21: nano structure | |
| 211: quantum dot | 212: silicide quantum dot |
| 30: second insulation film | |
| 31, 31a, 31b: trench | 40: third insulation film |
| 50: metal film | |
| G: gate | S: sidewall spacer |
| 100: lower conductive layer | |
| 200: upper conductive layer | |

### DETAILED DESCRIPTION OF EMBODIMENTS

Hereinafter, some exemplary embodiments of the present invention are described in detail in connection with specific embodiments with reference to the accompanying drawings.

### First Embodiment of the Present Invention

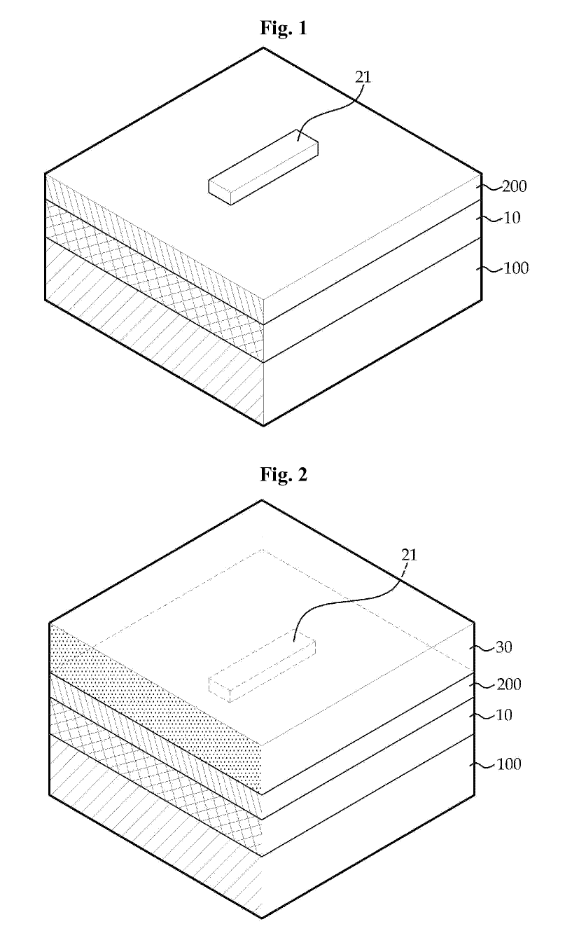

FIG. 1 is a cross-sectional perspective view showing a state in which a nano structure 21 is formed according to a first embodiment of the present invention. A first step is a process of forming the nano-wire structure 21. The nano structure 21 is formed over substrate. Here, a substrate to be used in the present invention has a first insulation film 10 formed between a lower conductive layer 100 and an upper conductive layer 200. Moreover, the nano-wire structure 21 is formed over the upper conductive layer 200.

Particularly, the nano-wire structure 21 is formed by forming a pattern on the upper conductive layer 200 using a photolithography process or an electron-beam lithography process and then etching a remaining portion other than the formed pattern. In FIG. 1, the nano structure 21 shows an example in which both sides thereof are exposed outside.

A second step is a process of implanting the upper conductive layer 200 with impurities. The impurity implanting is accomplished in a state in which the nano-wire structure 21 has been formed, and the implanting is conducted to change the number of carriers within a single-electron transistor according to the present invention. At this time, impurities used for the implanting can include, for example, phosphorous (P), arsenic (As), and boron (B), having a concentration of 1×10¹²/cm² or more.

In a preferable example, it is preferable to use the nano-wire structure 21 as a mask in implanting of impurities. It is for impurities to be evenly penetrated according to a concentration difference when a source and a drain, and a quantum dot 211 are formed on the upper conductive layer 200 under the nano-wire structure 21 according to a process which will be explained later.

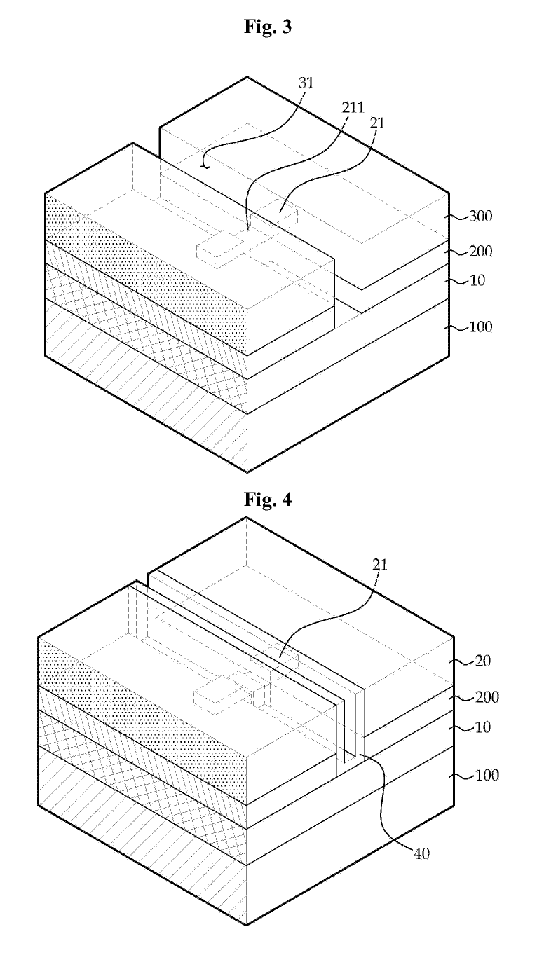

FIG. 2 is a sectional perspective view showing a state in which a second insulation film 40 is formed according to the first embodiment of the present invention. A third step is a process of forming a second insulation film 30 on the upper conductive layer 200 to surround the nano-wire structure 21. The second insulation film 30 may be formed over upper conductive layer 200 at a constant thickness or may have a constant surface on its top as in FIG. 2. The second insulation film 30 plays the role of an insulator for preventing carriers from moving to the outside of the upper conductive layer 200 and providing electrical insulation. The second insulation film 30 also functions as a diffusion barrier for selective implanting in implanting process.

In a preferred embodiment of the present invention, the second insulation film 30 preferably is formed using a deposition method. This is because the second insulation film 30 can be deposited on the top surface of the upper conductive layer 200 at a constant thickness and, particularly, the thickness of the second insulation film 30 can be easily controlled.

FIG. 3 is a sectional perspective view showing a state in which a quantum dot is formed according to the first embodiment of the present invention. A fourth step is a process of forming the quantum dot 211. The quantum dot 211 is formed by etching the second insulation film 30 and the nano-wire structure 21 until the upper conductive layer 200 is exposed. The etching can be performed using a dry etch process or a focus ion beam (FIB) method. At this time, a pattern (not shown) is formed in the middle of length of the nano-wire structure 21. It is for minimizing an overlapped portion between a gate G and the quantum dot 211 formed in a later process.

In particular, FIG. 3 shows an example in which the quantum dot 211 is defined by etching the upper conductive layer 200, the second insulation film 30, and the nano-wire structure 21 except for the upper conductive layer 200 at the bottom of the nano-wire structure 21. However, the quantum dot 211 may be defined by etching only a part of a thickness of the nano-wire structure 21.

FIG. 4 is a sectional perspective view showing a state in which a third insulation film is formed according to the first embodiment of the present invention. A fifth step is a process of forming the third insulation film 40. The third insulation film 40 is a kind of gate oxide film for insulating the quantum dot 211 and a gate G to be described later from each other. The third insulation film 40 is formed on the both sides of a trench 31, etched to form the quantum dot 211 of the fourth step by a thermal oxidation process. In particular, as the third insulation film 40 is produced by this thermal oxidation process, the width of the trench 31, i.e., the width of the gate G, formed in a subsequent process, can be further narrowed.

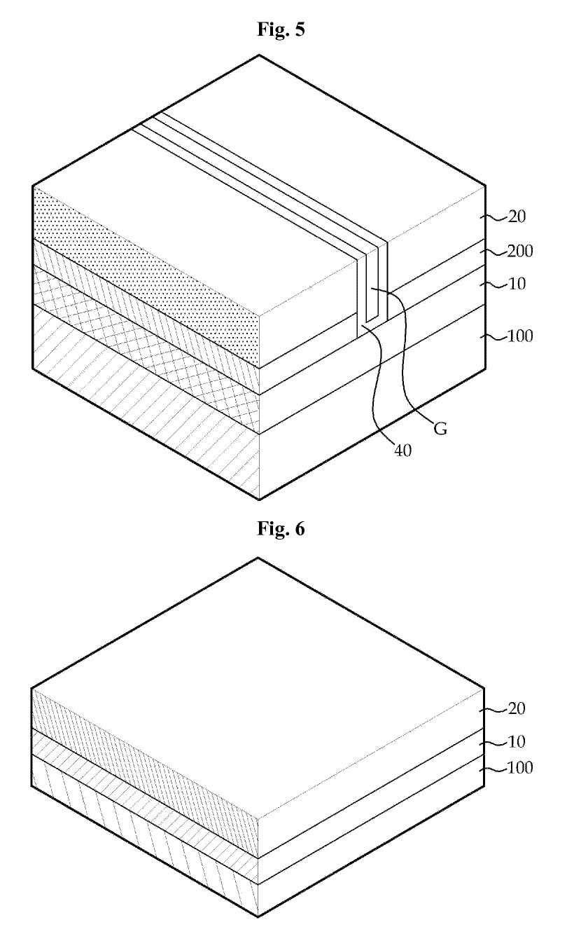

FIG. 5 is a sectional perspective view showing a state in which a gate is formed according to the first embodiment of the present invention. A sixth step is a process of forming the gate G. The gate G is provided between a top on which the quantum dot 211 is formed and the third insulation film 40 formed on either opposite side of the etched portion (trench) and the gate G is perpendicular with the nano-wire structure 21. Thus, in the fifth step, the nano-wire structure 21 separates into two gates about middle part thereof which is not totally etched.

This gate G can use Polysilicon, including impurities having a concentration of 1×10¹²/cm² or more. First of all, the polysilicon of the gate G is deposited over the quantum dot 211 and is etched to form only over the quantum dot 211, using a photolithography.

Meanwhile, the present invention comprises a single-electron transistor manufactured according aforementioned manufacturing methods.

### Second Embodiment of the Present Invention

FIG. 6 is a partially sectional perspective view showing an example of a substrate used in a method of manufacturing a single-electron transistor according to a second embodiment of the present invention. A substrate in which a first insulation film 10 and a conductive layer 20 are repeatedly stacked may be used in an exemplary embodiment of the present invention. However, a substrate 100 having a structure in which a lower conductive layer 100, the first insulation layer 10, and the conductive layer 20 are sequentially stacked, such as that shown in FIG. 1, is described as an example, for explanation convenience of the present invention. Furthermore, although various kinds of conductive materials may be used as the lower conductive layer 100 and the conductive layer 20, it is assumed that the lower conductive layer 100 and the conductive layer 20 are made of silicon. Further, it is assumed that the first insulation film 10 is formed of an oxide layer or an insulating film.

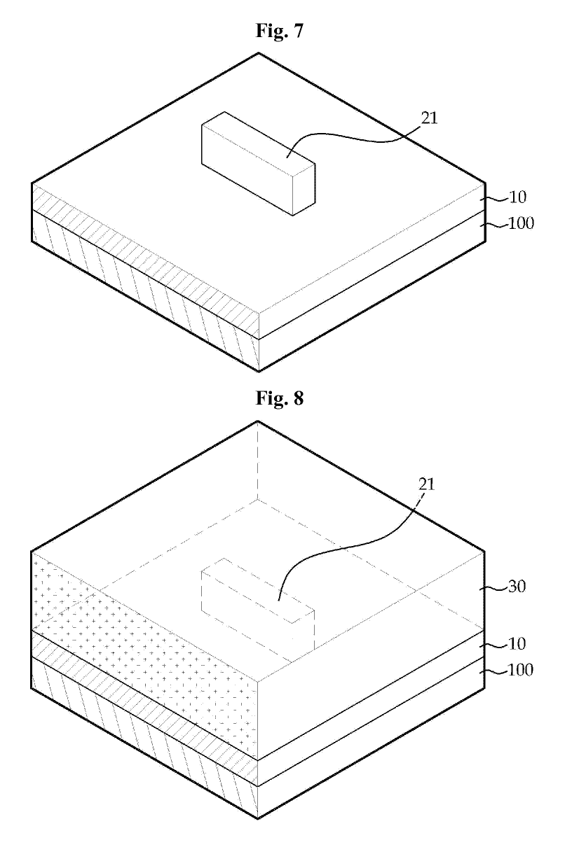

FIG. 7 is a partially sectional perspective view showing a state in which a nano-wire structure 21 according to a second embodiment of the present invention is defined. A first step is a process of defining the nano-wire structure 21 over the substrate 100. The nano-wire structure 21 is formed by etching the conductive layer 20. To this end, a pattern is formed over the conductive layer 20 using a photolithography process or an electron-beam lithography process, and a remaining portion except for the formed pattern of the conductive layer 20 is etched. The defined nano-wire structure 21 can preferably have a width of 1 to 9 nm and a length of 1 to 50 nm such that the total size of the transistor can be minimized.

FIG. 8 is a partially sectional perspective view showing a state in which a second insulation film is formed according to the second embodiment of the present invention. A second step is a process of forming the second insulation film 30 over the substrate 100 to surround the nano-wire structure 21.

In FIG. 8, the second insulation film 30 is fabricated with a planar shape having a constant thickness and surrounding the nano-wire structure 21, but which is not limited to that shape. Moreover, the second insulation film 30 may be formed in coating layer at a predetermined thickness. It is preferable to form the second insulation film with a constant thickness by a deposition process in which the thickness of the second insulation film 30 can be easily controlled.

The second insulation film 30 plays the role of an insulator for preventing carriers from moving to the outside of the upper conductive layer 200 and providing electrical insulation, as well as functions as a diffusion barrier in implanting process which will be described later.

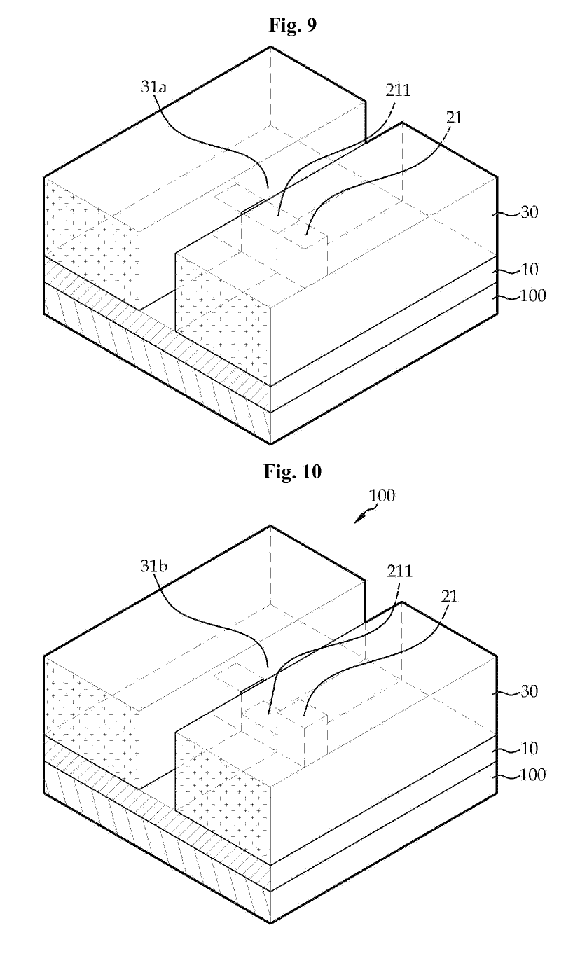

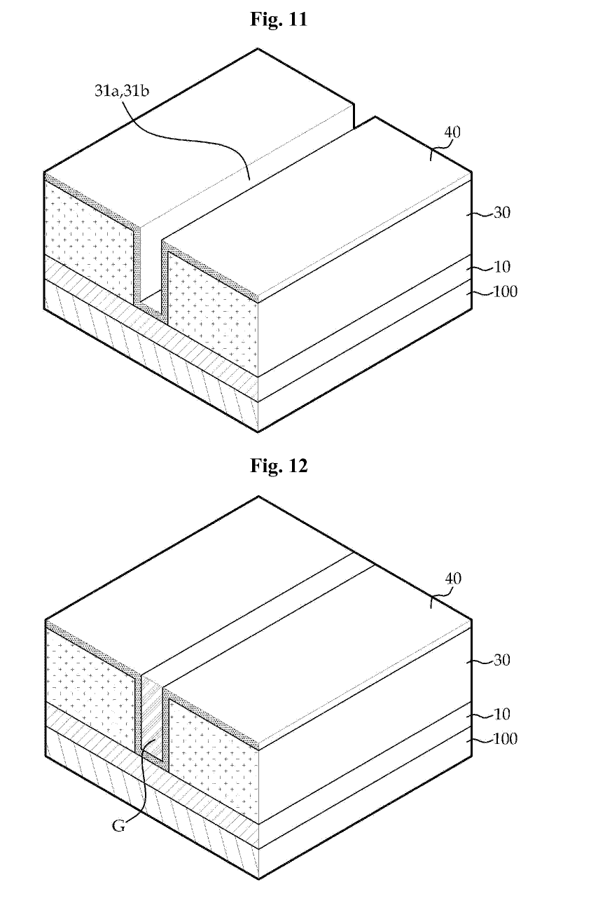

FIG. 9 is a partially sectional perspective view showing an example in which a quantum dot is formed according to the second embodiment of the present invention, and FIG. 10 is a partially sectional perspective view showing another example in which a quantum dot is formed according to the second embodiment of the present invention. A third step is a process of forming the quantum dot 211. The quantum dot 211 is formed by etching the trenches 31a, 31b so that the nano-wire structure 21 is exposed. It is preferable to form the trenches 31a, 31b perpendicularly to each other in the middle of length of the nano-wire structure 21, and the etching can be performed using a dry etch process or a focus ion beam (FIB) method. In addition, the etching layer of the trenches 31a, 31b are dependent on the formation of the nano-wire structure 21.

As shown in FIG. 9, the trench 31a is formed by etching only the second insulation film 30 so that the nano-wire structure 21 is exposed. In addition, as shown in FIG. 10, the trench 31b may be formed by etching a part of a thickness of the nano-wire structure 21 together with the second insulation film 30 in order to make thin the thickness of the quantum dot 211.

When the trenches 31a, 31b are formed as described above, the quantum dot 211, formed in the nano-wire structure 21 externally exposed can have 1 to 9 nm in width. In a preferable example of the present invention, it is desirable for the quantum dot 211 to be formed with 1 to 50 nm in length so as to have the minimum size. It is for minimizing an overlapped portion between a gate G and the quantum dot 211 formed in a later process.

FIG. 11 is a partially sectional perspective view showing a state in which a third insulation film is formed according to the second embodiment of the present invention. A fourth step is a process of forming the third insulation film 40 on the top surface of the substrate 100. The third insulation film 40 is a gate oxide film for insulating the quantum dot and a gate G to be described later from each other. This third insulation film 40 is formed on the surface of the second insulation film 30 and the surfaces of each of the trenches 31a, 31b at a constant thickness.

Like this, because the width of the trenches 31a, 31b is further reduced as much as the third insulation film 30 is formed, the width of the gate G, formed in a subsequent process, can be further narrowed. It is preferable to form the third insulation film 40 as an oxidation film by a thermal oxidation process, or a deposition process subsequent to a thermal oxidation process. FIG. 11 shows an example in which the third insulation film 40 is formed by a deposition process subsequent to a thermal oxidation process.

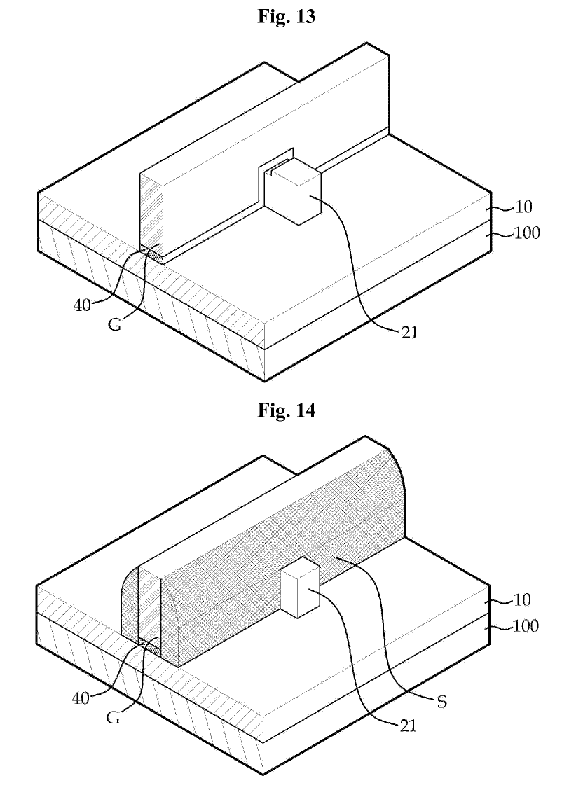

FIG. 12 is a partially sectional perspective view showing a state in which the gates G are formed according to the second embodiment of the present invention. A fifth step is a process of forming the gates G. The gates G are formed by filling the trenches 31a, 31b with conductive material. The quantum dot 211 is formed by etching each of the trenches 31a, 31b, and is surrounded by the third insulation film 40. Then the conductive material is filled in the trench, thereby forming the gate G. This conductive material can use Polysilicon, including impurities having a concentration of 1×10¹²/Cm² or more, The impurities can include, for example, phosphorous (P), arsenic (As), and boron (B).

Meanwhile, a method of manufacturing a single-electron transistor can further comprise a sixth step of etching a part of the third insulation film 40 formed in the fourth step, and a seventh step of implanting impurities so that an electric current is applied in the transistor.

FIG. 13 is a partially sectional view showing a state in which the third insulation film 40 is etched according to the second embodiment of the present invention. The sixth step is a process of etching the third insulation film 40. The third insulation film 40, formed by the deposition process in the fourth step, can be etched so that it remains only on the sidewalls of the trenches 31a, 31b. Here, the gate oxide film includes only the first gate oxide film formed by the thermal oxidation process.

The seventh step is a process of implanting impurities in order to form the source and the drain. The second insulation film 30 and the third insulation film 40 are etched by a dry etch process so that the impurities can be implanted, and the impurities are then implanted using the gate G as a mask.

In a preferred embodiment of the present invention, the seven step shows fully etching the second insulation film 30 and the third insulation film 40, but a thickness with which impurity implanting can be accomplished, for example only ⅔ of thickness of the second insulation film 30, can be etched. Moreover, the implanting can be carried out after forming sidewall spacers.

FIG. 14 is a partially sectional perspective view showing a sidewall spacer is formed in the etched state of the third insulation, as shown in FIG. 13. The method of forming the sidewall spacers is as shown in FIG. 14. After an insulating film (i.e., a silicon oxide film or a silicon nitride film) is deposited as much as the formed thickness of gate G, the sidewall spacers S are formed on the sidewalls of the gate G by performing a dry etch process as much as the deposited thickness.

Here, when impurity implanting is performed, only the exposed portion of the nano-wire structure 21 is implanted using the gate G and the sidewall spacers S as a mask.

The implantation method is performed according to a common implantation method, and a detailed description thereof is omitted.

In a preferable example, impurities used for implantation can include phosphorous (P), arsenic (As), and boron (B).

Meanwhile, the present invention includes single-electron transistors manufacturing according to the above-described manufacturing methods. Further, the single-electron transistors can use a lower conductive layer 100 as a lower gate.

### Third Embodiment of the Present Invention

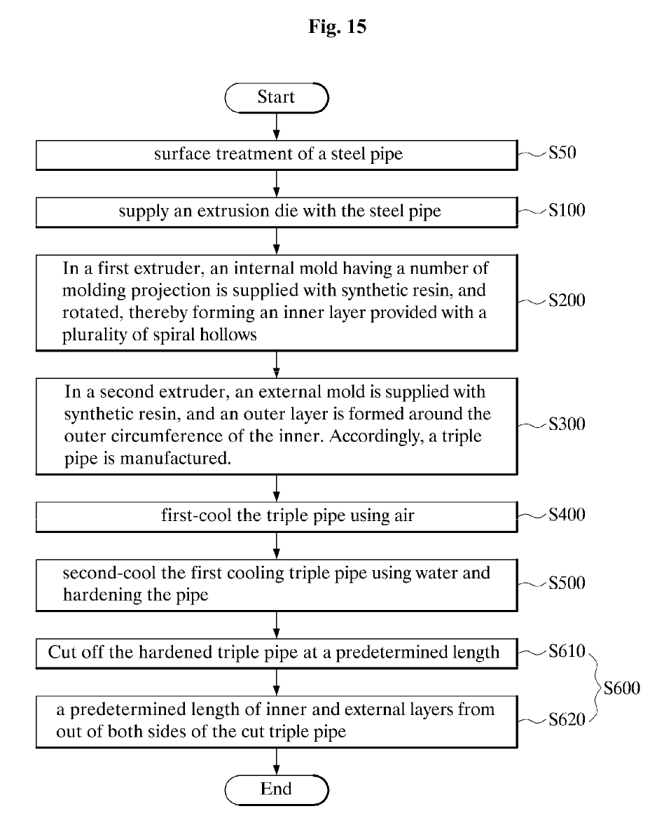

FIG. 15 is a flow chart showing a method of manufacturing a single-electron transistor operating at room temperature according to a third embodiment of the present invention. The method of manufacturing a single-electron transistor operating at room temperature is explained by referring partially sectional prospective views and cross-sectional views according the below steps, together with the flow chart shown in FIG. 1.

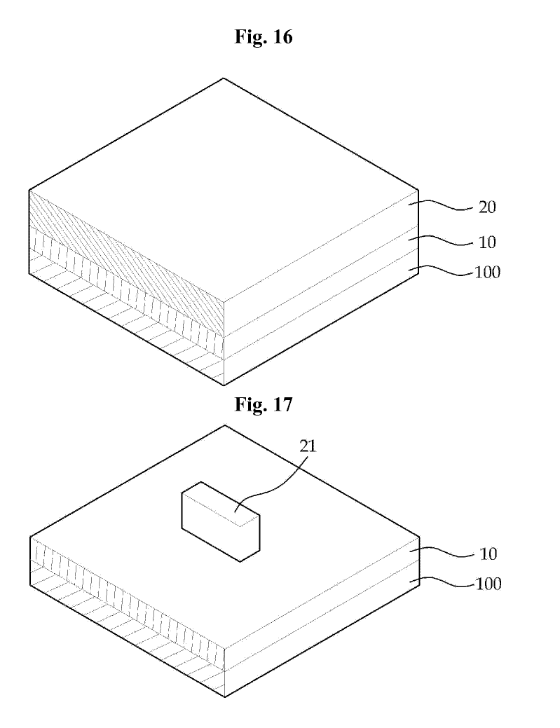

FIG. 16 is a perspective view showing an example of a substrate to be used for a method of manufacturing a single-electron transistor according to the third embodiment of the present invention. A substrate in which a first insulation film 10 and a conductive layer 20 are repeatedly stacked may be used as the substrate used in an exemplary embodiment of the present invention. However, a SOI substrate having a structure in which a lower conductive layer 100, the first insulation layer 10, and the conductive layer 20 are sequentially stacked, such as that shown in FIG. 1, is described as an example, for the convenience of explanation.

Furthermore, although various kinds of conductive materials may be used as the lower conductive layer 100 and the conductive layer 20, it is assumed that the lower conductive layer 100 and the conductive layer 20 are made of silicon.

Further, it is assumed that the first insulation film 10 is formed of an oxide layer or an insulating film.

FIG. 17 is a partially sectional perspective view showing a state in which a nano structure is defined according to the third embodiment of the present invention. As shown in FIG. 17, the nano structure 21 is formed by etching the conductive layer 20 in a first step S100. To this end, a pattern is formed over the conductive layer 20 using a photolithography process or an electron-beam lithography process, and a remaining portion except for the formed pattern of the conductive layer 20 is etched.

The nano structure 21 can preferably have a width of 1 to 50 nm and a length of 1 to 500 nm such that the total size of the transistor can be minimized.

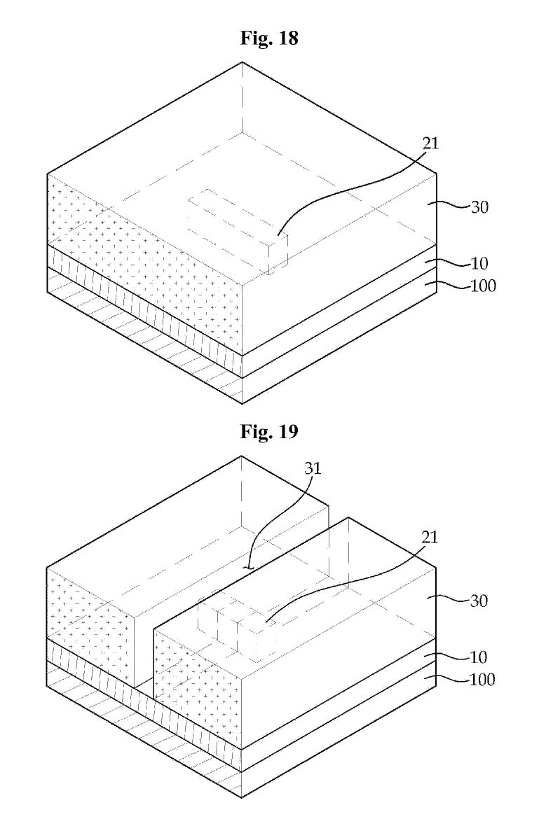

FIG. 18 is a partially sectional perspective view showing a state in which a second insulation film is formed according to the third embodiment of the present invention. As shown in FIG. 18, the second insulation film 30 is formed over the substrate so that the nano structure 21 is covered in a second step S 200. The second insulation film 30 is fabricated such that the nano structure 21 is surrounded and covered with a planar shape having a constant thickness.

Moreover, the second insulation film 30 may be formed in coating layer at a predetermined thickness, by which the nano structure 21 is surrounded. It is preferable to form the second insulation film with a constant thickness by a deposition process in which the thickness of the second insulation film 30 can be easily controlled.

The second insulation film 30 plays the role of an insulator for preventing carriers from moving to the outside of the upper conductive layer 200 and providing electrical insulation, as well as functions as a diffusion barrier in implanting process.

FIG. 19 is a partially sectional perspective view showing a state in which a trench is formed according to the third embodiment of the present invention. As shown in FIG. 19, a trench 31 is formed by etching only the second insulation film 30 such that a portion of the nano structure 21 is exposed in a third step S300.

It is preferable to make the trench 31 perpendicular with respect to the middle of length of the nano structure 21 and the trench 31 is formed by performing a dry etch process after forming 1 to 50 nm in single-line width using a photolithography process or an electron-beam lithography process.

The etching layer of the trench 31 is dependent on the formation of the nano structure 21.

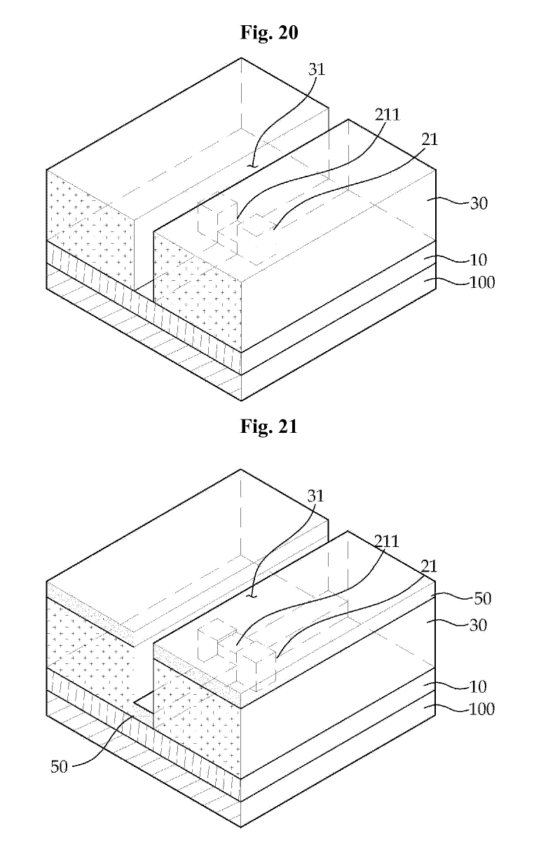

FIG. 20 is a partially sectional perspective view showing a state in which a quantum dot is formed according to the third embodiment of the present invention. As shown in FIG. 20, the quantum dot is formed by etching the nano structure 21 in a fourth step S400. The quantum dot 211 may be formed by etching a part of a thickness of the nano structure 21 in order to make thin the thickness of the quantum dot 211.

The quantum dot 211 formed in the nano structure 21 externally exposed can have 1 to 50 nm in width, but the quantum dot 211 can have 1 to 10 nm in length such that an overlapped portion between a gate G and the quantum dot 211 to be described later from each other is minimized.

FIG. 21 is a partially sectional perspective view showing a state in which a metal film is deposited according to the third embodiment of the present invention. As shown in FIG. 21, a metal material is deposited over the second insulation film 30, the trench 31 and the quantum dot 211, thereby forming the metal film 50 in a fifth step S500. The material of the metal film 50 may include any kind of metal that can be silicided, but preferably includes cobalt (Co). Moreover, the material of the metal film 50 may include any kind of metal that can react to silicon.

The metal film 50 preferably is formed to a thickness of 0.1 to 10 nm using an electron-beam evaporator or a molecular beam epitaxy (MBE) equipment.

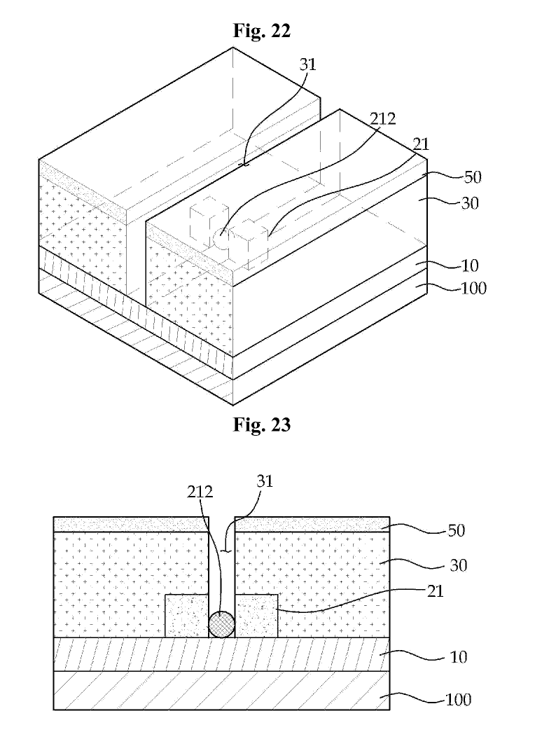

FIG. 22 is a partially sectional perspective view showing a state in which a silicide quantum dot is formed according to the third embodiment of the present invention; and FIG. 23 is a cross-sectional view showing a first example of a silicide quantum dot according to the third embodiment of the present invention. As shown in FIGS. 22-23, the metal film 50 and the quantum dot 211 are reacted by a thermal annealing process, thereby forming the silicide quantum dot 212 in a sixth step SG0. A metal dot silicidation is performed by any one of an electron-beam lithography process, RTA, Furnace, and other thermal treatment devices.

The silicide quantum dot 212 is formed only on a portion where the metal film 50 and the quantum dot 211 come in contact with each other. Here, the second insulation film 30 and the metal film 50 which is formed over the first insulation film 10 exposed by the trench 21 are not bonded from each other, so that the metal film 50 on the portion is not silicided.

It is preferable to form the silicide quantum dot 212 such that each of 1˜50 silicide quantum dots 211 having about 1 to 10 nm sizes is formed in parallel or in series. It is because that total capacitance of a single-electron transistor can be reduced.

Aforementioned factors forming the silicide quantum dot 211 are determined by the width of nano structure 21 or the width of trench 31. In other word, as the width of trench 31 is larger, a number of silicide quantum dots are formed in series, while a number of silicide quantum dots are formed in parallel as the width of nano structure 21.

Explaining an example of forming the silicide quantum dot 211, when the width of nano structure 21 is 6 nm and the width of trench 31 is 6 nm, one silicide quantum dot 211 is formed. When the width of nano structure 21 is 6 nm and the width of trench 31 is 12 nm, two silicide quantum dots 211 are formed in parallel.

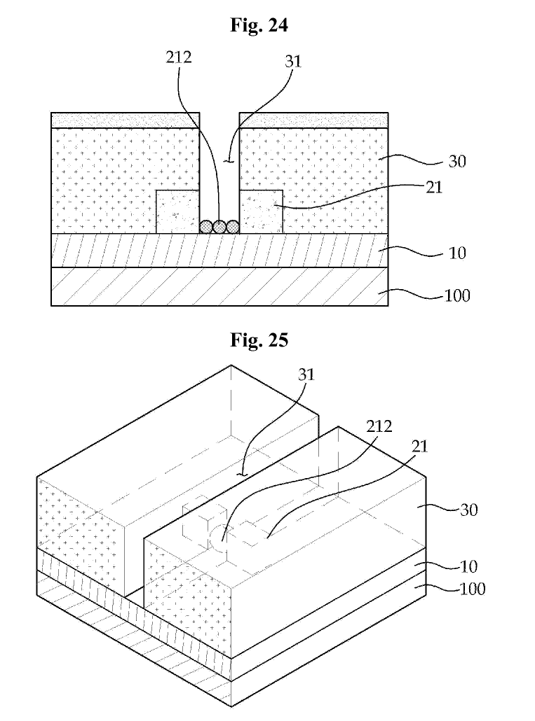

FIG. 24 is a cross-sectional view showing a second example of a silicide quantum dot according to the third embodiment of the present invention. As shown in FIG. 24, a number of silicide quantum dots are formed, and which is accomplished by controlling the size of trench 31.

FIG. 25 is a partially sectional perspective view showing a state a metal film is removed according to the third embodiment of the present invention. As shown in FIG. 25, the metal film 50 which has not reacted with the quantum dot 211 and accordingly has not form the silicide quantum dot 212 is removed in a seventh step S700.

As said before, the non-silicided metal film 50 preferably is removed using a mixed solution of sulfuric acid and hydrogen peroxide. Further, the non-silicided metal film 50 may be removed by partially or fully removing the second insulation film 30 by wet-etching.

FIG. 26 is a partially sectional perspective view showing a state in which a third insulation film is formed according to the third embodiment of the present invention. As shown in FIG. 26, the third insulation film 40 is deposited over the second insulation film from which the metal film 50 is removed in an eight step S800. The third insulation film 40 is deposited on the portion from which the metal film 50 is removed, and both sides of trench 31, including the silicide quantum dot 212.

The third insulation film 40 is a gate oxide film for insulating the quantum dot and a gate G to be described later from each other. The third insulation film 40 is deposited at a constant thickness on the entire surface, including the second insulation film 30 and the each trench 31.

The third insulation film 40 can control the width of gate G formed in subsequent processes to be described later, and the width of trench 31 is controlled dependent on the thickness of the third insulation film 40. When the thickness of the third insulation film 40 is thin, the width of gate G together with the width of trench 31 is larger. When the thickness of the third insulation film 40 is thicker, the width of gate G together with the width of trench 31 is smaller.

The third insulation film 40 preferably may be formed by a deposition process, by a thermal oxidation process, or by a deposition process subsequent to a thermal oxidation process.

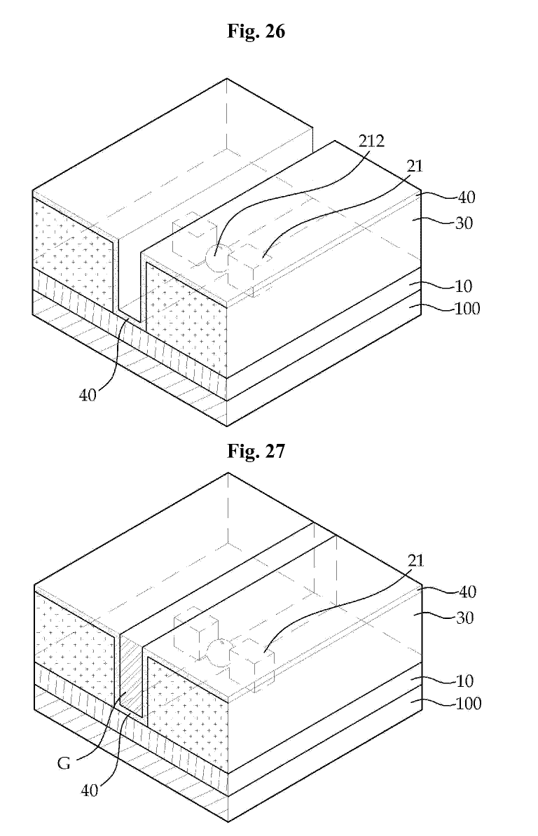

FIG. 27 is a partially sectional perspective view showing a state in which a gate is filled up according to the third embodiment of the present invention. As shown in FIG. 27, the gate G is formed on the trench 31 over which the third insulation film 40 is deposited in a ninth step S900. The gate G is formed in such a way to fill the trench 31 with conductive material.

In a preferable example of forming the gate G, the conductive material exist only in the trench by performing a dry etch process as much as the deposited thickness of the conductive material, but the gate also can be formed in portions other than the trench 31.

The silicide quantum dot 212 is surrounded by the third insulation film 40, and the conductive material is filled over the film, thereby forming the gate G. This conductive material can include Polysilicon, including impurities having a concentration of 1×10¹²/cm² or more. At this time, the impurities can include, for example, phosphorous (P), arsenic (As), and boron (B).

A second example of the eighth step S800 and the ninth step S900 is explained as below.

A method of manufacturing a single-electron transistor according to the present invention further comprises the eight step of etching partially or fully the third insulation film 40 formed in the eighth step of the first embodiment, and the ninth step of implanting impurities such that an electric current is applied in the transistor.

FIG. 28 is a cross-sectional perspective view showing a state in which second and third insulation films are etched according to the third embodiment of the present invention. As shown in FIG. 21, the eighth step is a process of etching the second insulation film 30 and the third insulation film 40. With remaining only the third insulation film 40 under the gate G, the second and third insulation films 30, 40 can be partially or fully etched.

The ninth step is a process of implanting impurities in order to form the source and the drain. The second insulation film 30 and the third insulation film 40 are etched by a dry etch process and the impurities are then implanted using the gate G as a mask.

In a preferred embodiment of the present invention, the eighth step shows fully etching the second insulation film 30 and the third insulation film 40, but a thickness with which impurity implanting can be accomplished, for example only ⅔ of thickness of the second insulation film 30, can be etched.

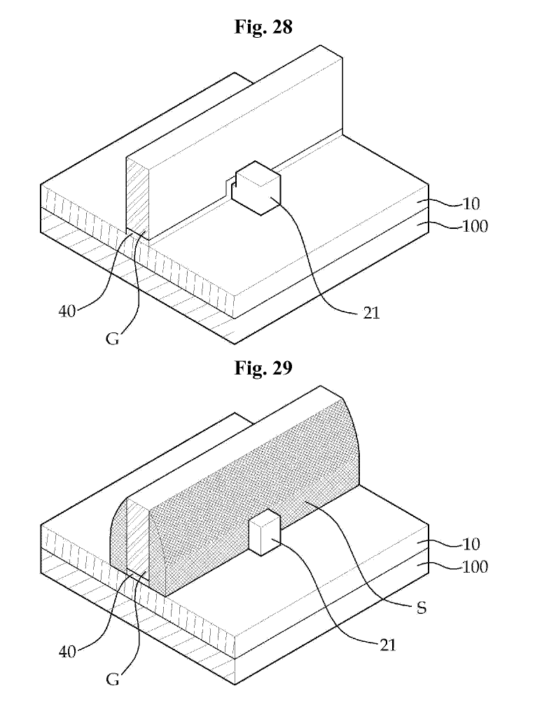

FIG. 29 is a cross-sectional perspective view showing that a sidewall spacer is formed in the etched state of the second and third insulation films, as shown in FIG. 28. As shown in FIG. 29, implanting can also be carried out after forming the sidewall spacers. The method of forming sidewall spacers includes the following steps. As shown in FIG. 22, after an insulating film (i.e., a silicon oxide film or a silicon nitride film) is deposited as much as the formed thickness of gate G, the sidewall spacers S are formed on the sidewalls of the gate G by performing a dry etch process as much as the deposited thickness.

Here, when impurity implanting is performed, only the exposed portion of the nano structure 21 is implanted using the gate G and the sidewall spacers S as a mask.

The implantation method is performed according to a common implantation method, and a detailed description thereof is omitted.

In a preferable example, impurities used for implantation can include phosphorous (P), arsenic (As), and boron (B).

The single-electron transistor according to the present invention, as described above can use the lower conductive layer 100 as a lower gate.

Meanwhile, the present invention includes single-electron devices which is manufactured by the above-described methods and operated at room temperature.

### INDUSTRIAL APPLICABILITY

The present invention can be applied to single-electron transistors operating at room temperature and a method of manufacturing the same, which are capable of minimizing influence on a tunneling barrier by a gate, effectively controlling the electric potential of a quantum dot, and improving the efficiency of an operation.

What is claimed is:

1. A method of manufacturing a single-electron transistor (SET) operating at room temperature, the method comprising:
a first step of forming a nano structure over an upper conductive layer 200 of a substrate in which a lower conductive layer 100, a first insulation film 10, and the upper conductive layer 200 are stacked;
a second step of implanting the upper conductive layer 200 with impurities using the nano structure 21 as a mask;
a third step of forming a second insulation film 30 over the upper conductive layer 200 so that the nano structure 21 is covered;
a fourth step of etching the upper conductive layer 200 and the second insulation layer 30, thereby forming a quantum dot 211;
a fifth step of forming a third insulation film G by a thermal oxidation process to surround the quantum dot 211; and,
a sixth step of forming a gate G over the quantum dot 211.

2. A method of manufacturing a single-electron transistor (SET) operating at room temperature, wherein a quantum dot 211 is formed by fully etching a nano structure 21 and a second insulation film 30 and etching a part of a thickness of an upper conductive layer 200, or the quantum dot 211 is formed by etching a part of the nano structure 21, together with the upper conductive layer 200 and the second insulation film 30.

3. A method of manufacturing a single-electron transistor (SET) operating at room temperature using a substrate 100 in which at least one first insulation film 10 and a conductive layer 20 are stacked, the method comprising:
a first step of defining a nano structure 21 over a substrate 100;
a second step of forming a second insulation film 30 over the substrate 100 so that the nano structure 21 is covered;
a third step of etching trenches (31a, 31b) to expose the nano structure 21, and thereby forming a quantum dot 211;
a fourth step of forming a third insulation film 40 with a constant thickness on surfaces of the second insulation film 30 and the trenches (31a, 31b); and
a fifth step of forming a gate in the trenches (31a, 31b) so that the gate G is positioned over the quantum dot 211.

4. The method as claimed in claim 3, wherein the first, second, and third insulation films 10, 30, 40 are an oxidation film or an insulation film, and the conductive layer 20 is silicon.

5. The method as claimed in claim 3, wherein between the fourth step and the fifth step, a sixth step of etching the plane layer of the third insulation film 40, formed by a deposition process; and a seventh step of implanting regions other than the quantum dot 211 with impurities using the gate G as a mask after etching the second insulation film 30 and the third insulation film 40, can be further included.

6. The method as claimed in claim 3, further including a lower conductive layer 100 under the first insulation layer 10, which is used as a lower gate.

7. The method as claimed in claim 5, wherein the seventh step further comprises forming sidewall spacers S in the gate G, and the seventh step is characterized by using the gate G and the sidewalls S as a mask.

8. A method of manufacturing a single-electron transistor (SET) operating at room temperature, the method comprising:
a first step S100 of forming a nano structure 21 by etching a conductive layer 20 of a SOI substrate in which a first insulation film 10 and the conductive layer 20 are sequentially stacked;
a second step S200 of depositing a second insulation film 30 over the substrate so that the nano structure 21 is covered;
a third step S300 of forming a trench 31 by etching a portion of the second insulation film 30 so that a part of the nano structure 21 is exposed;
a fourth step S400 of etching the exposed nano structure 21, thereby forming a quantum dot 211;
a fifth S500 step of forming a metal film 50 by depositing metal material over the second insulation film 30, the trench 31 and the quantum;
a sixth step S600 of forming a silicide quantum dot 212 by performing an thermal annealing process for the metal film 50 and the quantum dot 211;
a seventh step S700 of removing the metal film 50 which has not reacted to the quantum dot 211;
a eight step S800 of depositing a third insulation film 40 on the silicide quantum dot 212 and surfaces from which the metal film 50 has been removed; and
an ninth step S900 of filling the trench on which the third insulation film 40 is deposited with a gate.

9. The method as claimed in claim 8, wherein the eight step S800 includes depositing the third insulation film 40 after fully or partially removing a second insulation film 30

10. The method as claimed in claim 9, wherein the ninth step further comprises forming sidewall spacers S in the gate G and, the ninth step is characterized by implanting impurities using the gate 90 and the sidewall spacers S as a mask, thereby forming a source and a drain.

11. The method as claimed in claim 8, wherein the first, second, and third insulation films 10, 30, 40 are an oxidation film or an insulation film, and the conductive layer 20 is silicon.

12. The method as claimed in claim 8, further including a lower conductive layer 100 under the first insulation layer 10, which is used as a lower gate.

13. A single-electron transistor (SET) operating at room temperature, manufactured by a method according to any one of claims 1 to 12.
